(19) United States
(12) Patent Application Publication
(10) Pub. No.: US 2025/0048597 A1
(43) Pub. Date: Feb. 6, 2025

(54) CONNECTOR

(71) Applicant: Yazaki Corporation, Tokyo (JP)

(72) Inventors: Hideki HOMMA, Tokyo (JP); Yasuaki Ito, Tokyo (JP); Tomoyoshi Fukaya, Makinohara-shi (JP)

(73) Assignee: Yazaki Corporation, Tokyo (JP)

(21) Appl. No.: 18/761,942

(22) Filed: Jul. 2, 2024

(30) Foreign Application Priority Data
Aug. 2, 2023 (JP) 2023-126169

(51) Int. Cl. H05K 7/20; H01R 13/41; H01R 13/50

(52) U.S. Cl. CPC H05K 7/20509; H01R 13/41; H01R 13/50

(57) ABSTRACT

A connector is a configuration assembled into a wire harness for automobile vehicle to dispute electric power, and the connector includes a plurality of busbars and a housing to accommodate these busbars. The housing includes a busbar holding portion at one side thereof, and a terminal accommodation room at the other side thereof to accommodate a terminal that is electrically connected to the busbar. The busbar holding portion includes a pair of clamping plates that clamp the busbar from both sides in a thickness direction thereof. The housing includes a plurality of heat dissipation plates standing vertically from the clamping plates respectively. Also, the heat dissipation plate that is standing from the clamping plate of the busbar holding portion in the upper segment to the busbar holding portion in the lower segment is spaced apart from the clamping plate of the busbar retention plate in the lower segment.

### TECHNICAL FIELD

The present invention relates to a connector including a busbar and a housing.

### BACKGROUND ART

A connector (also referred to as a “joint connector”) for an automotive vehicle that includes a busbar and a housing and is configured to connect a plurality of terminals with each other is known.

For example, a connector described in Patent Document 1 includes a busbar from which a plurality of tab terminals extend from a strip-shaped base plate portion, and a housing that accommodates this busbar. A busbar holding groove in which the base plate portion is held is formed on one side of the housing, and an accommodation space in which a plurality of tab terminals are accommodated is formed on the other side. A female terminal connected to the terminal of the electric wire is inserted into this accommodation space, and the female terminal is fitted with the tab terminal. Such a connector interconnects the female terminals fitted into a plurality of tab terminals.

### CITATION LIST

### Patent Documents

[Patent Document 1] JP H8-17531A

### SUMMARY OF THE INVENTION

### Technical Problem

There is a problem in the above-described connector disclosed in Patent Document 1 that when current flows in an order as from the electric wires to the terminals and to the busbars, the Joule heat is generated to lead to a high temperature inside the housing, and there is room for improvement.

Accordingly, an object of the present invention is to improve the heat dissipation performance of a connector including a busbar and a housing.

### Solution to Problem

The present invention corresponds to a connector including a busbar; and a housing that accommodates the busbar, wherein the connector is characterized in that the housing includes a busbar holding portion at one side thereof, and the busbar holding portion includes a pair of clamping plates that clamp the busbar from both sides in a thickness direction thereof, the housing includes a terminal accommodation room at the other side thereof to accommodate a terminal that is electrically connected to the busbar, and the housing includes a heat dissipation plate standing from one of the pair of clamping plates.

### Effect of the Invention

According to the present invention, since the housing includes the heat dissipation plate standing from one of the pair of clamping plates that sandwich the busbar, it is possible to improve the heat dissipation performance.

### BRIEF DESCRIPTION OF THE DRAWINGS

FIG. 1 is a view showing a connector according to an embodiment of the present invention.

FIG. 2 is an exploded view showing the connector in FIG. 1.

FIG. 3 is a cross-sectional view showing the connector in FIG. 1 taken in a transverse direction.

FIG. 4 is a cross-sectional view showing the connector in FIG. 1 taken in a longitudinal direction.

FIG. 5 is a view showing functions of the connector in FIG. 1.

### DESCRIPTION OF EMBODIMENTS

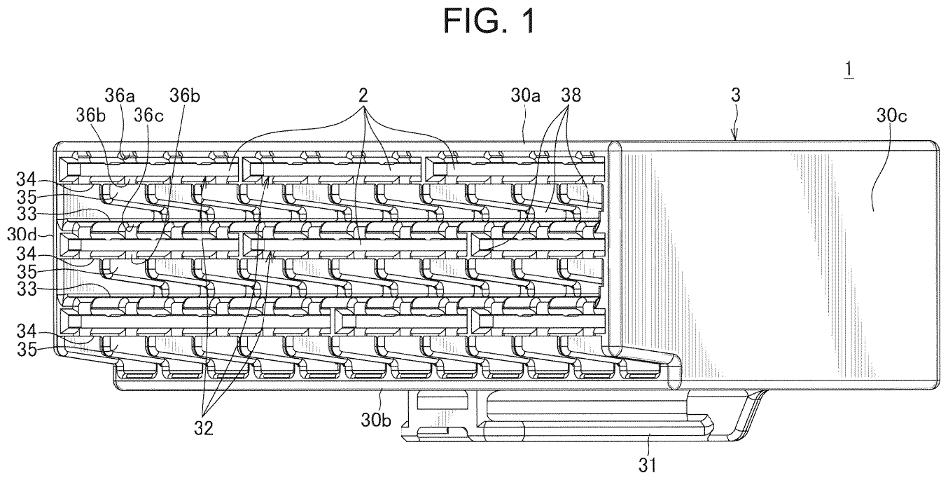

A “connector” according to an embodiment of the present invention will be described by referring from FIG. 1 to FIG. 5.

A connector 1 as an example shown in FIG. 1 to FIG. 5 is incorporated into a wire harness for automobile vehicle to distribute electric power. The connector 1 includes a plurality of busbars 2 and a housing 3 that accommodates these busbars 2.

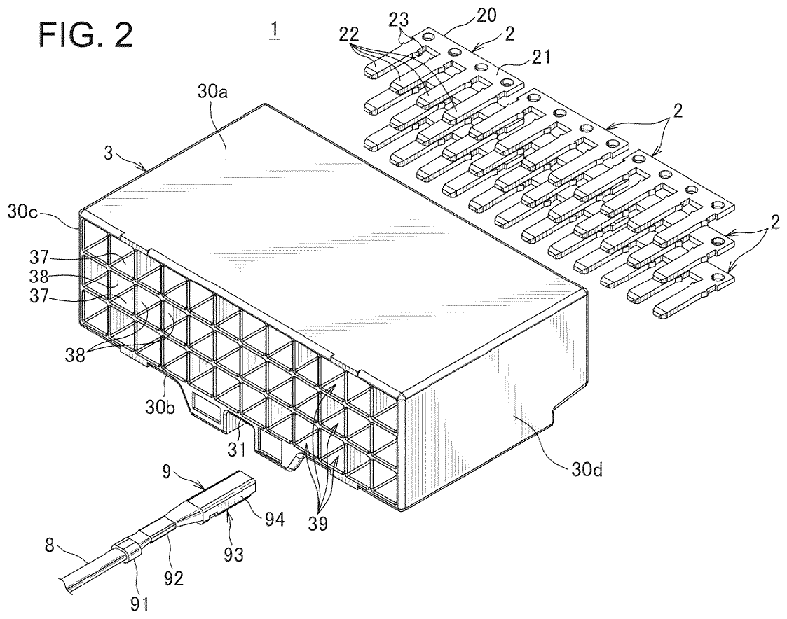

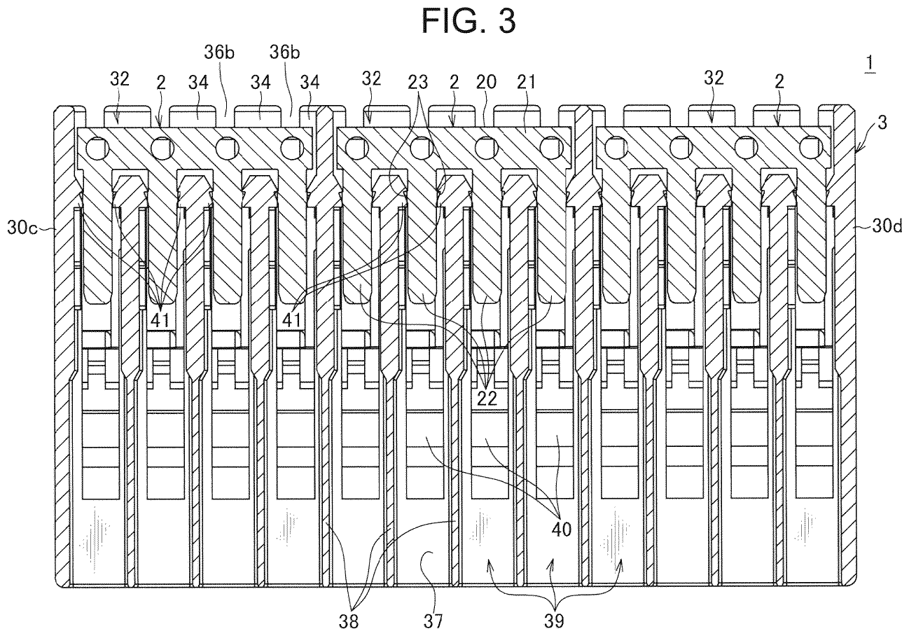

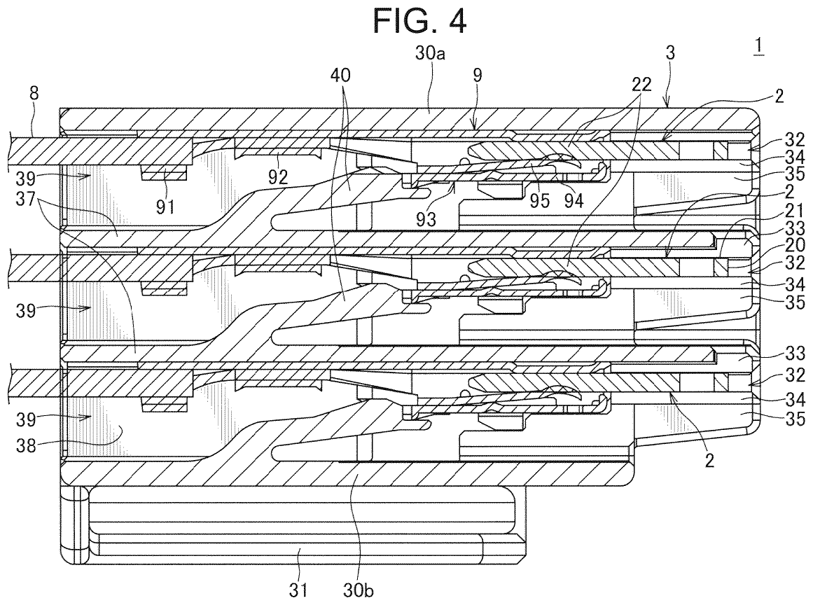

The busbar 2 is obtained by pressing a metal plate or the like, and as shown in FIG. 2, a plurality of tab terminals 22 extend from a strip-shaped base plate portion 21. The tab terminal 22 is formed into a tongue shape and extends perpendicularly to a longitudinal direction of the base plate portion 21. As shown in FIG. 2 and FIG. 3, a retention protrusion 23 that is retained onto the housing 2 is formed at a base end of the tab terminal 22 near the base plate portion 21. As shown in FIG. 4, the tip side of the tab terminal 22 is fitted with a female terminal 9 connected to a terminal of the electric wire 8. It is noted that in FIG. 3, any illustration for the terminal 9 is omitted.

The housing 3 is made of insulating synthetic resin. The housing 3 is formed into a rectangular cylindrical shape having an upper wall 30a, a lower wall 30b, and a pair of left and right side walls 30c, 30d. The housing 3 has a busbar holding portion 32 on its rear side (one side), and a terminal accommodation room 39 for accommodating a terminal 9 that is electrically connected to the busbar 2 on its front side (the other side). Also, a retention portion 31 for attaching the housing 3 to a structure (vehicle body, electrical connection box, electronic unit, and the like) is provided on the outer surface of the lower wall 30b.

It is noted that the names such as “upper wall 30a”, “lower wall 30b”, “side walls 30c, 30d” and the like are merely used for convenience of explanation in this specification, and it is unnecessary to match the actual left side, right side, front side and rear side in a state in which the connector 1 is mounted on an automobile vehicle.

As shown in FIG. 2, in the present example, twelve terminal accommodation rooms 39 are lined up in a transverse direction of the housing 3 (the direction in which the side wall 30c and the side wall 30d face each other), and the group of these terminal accommodation rooms 39 in the transverse direction are arranged in three segments in an up-down direction (the direction in which the upper wall 30a and the lower wall 30b face each other) of the housing 3. These terminal accommodation rooms 39 are configurations that are partitioned by eleven vertical partition walls 38 provided between the side wall 30c and the side wall 30d, and two horizontal partition walls 37 provided between the upper wall 30a and the lower wall 30b. As shown in FIG. 3 and FIG. 4, each terminal accommodation room 39 is provided with a lance 40 that is retained with the terminal 9.

The terminal 9 is obtained by subjecting a metal plate to press processing or the like. As shown in FIG. 2 and FIG. 4, the terminal 9 includes a covering crimping piece 91 which crimps the part covered with a covering at the terminal of the electric wire 8, a core wire crimping piece 92 which crimps the exposed core wire in which the covering is peeled off, and a fitting portion 93. The fitting portion 93 has a square cylindrical portion 94 that receives the tab terminal 22 and a spring piece 95 which comes into elastic contact with the tab terminal 22 inserted into the square cylindrical portion 94.

As shown in FIG. 1, in the present example, three busbar holding portions 32 are lined up in the transverse direction of the housing 3, and the group of these transverse busbar holding portions 32 are provided in three segments in the up-down direction of the housing 3. The busbar 2 is accommodated in the housing 3 in such a manner that the longitudinal direction of the base plate portion 21 coincides with the transverse direction of the housing 3, and the thickness direction thereof coincides with the up-down direction of the housing 3.

The busbar holding portion 32 includes a pair of clamping plates 33, 34 that sandwich the busbar 2 from both sides in the thickness direction. The clamping plate 33 is connected to the rear end of the horizontal partition wall 37 and extends rearward. The clamping plate 34 is connected to the rear end of the vertical partition wall 38 and extends rearward. Regarding the busbar holding portion 32 at the top segment, the upper wall 30a serves as the clamping plate 33, and the busbar 2 is sandwiched between the upper wall 30a and the clamping plate 34. As shown in FIG. 3, between the adjacent busbar holding portions 32, they are separated from each other by the vertical partition wall 38 extending to the rear end of the housing 3. Thus, short circuits between the adjacent busbars 2 are prevented.

As shown in FIG. 3, the internal space of the busbar holding portion 32 communicates with the internal space of the terminal accommodation room 39. A retained portion 41 to which the retention protrusion 23 of the busbar 2 is retained is formed at the boundary between the busbar holding portion 32 and the terminal accommodation room 39.

The busbar 2 is inserted into the busbar holding portion 32 from the rear end side of the housing 3, and the retention protrusion 23 is retained to the retained portion 41 of the housing 3 so as to be assembled into the housing 3. In the busbar 2 assembled into the housing 3, the base plate portion 21 is positioned in the busbar holding portion 32, and the plurality of tab terminals 22 are respectively positioned in the plurality of terminal accommodation rooms 39.

Also, when the busbar 2 is assembled into the housing 3, the rear end surface 20 of the base plate part 21 is pressed by a jig so as to be inserted into the busbar holding portion 32. Accordingly, jig guide grooves 36a, 36b, 36c are formed in the busbar holding portion 32.

Furthermore, the housing 3 includes a plurality of heat dissipation plates 35 standing from the clamping plates 34. Each heat dissipation plate 35 is standing vertically from the clamping plate 34 and continues to the rear end of the vertical partition wall 38. Also, the heat dissipation plate 35 that is standing (hanging down) from the clamping plate 34 of the busbar holding portion 32 in the upper segment to the busbar holding portion 32 in the lower segment is spaced apart from the clamping plate 33 in the busbar holding portion 32 in the lower segment. Also, as shown in FIG. 4, the longitudinal direction of the heat dissipation plate 35 coincides with both of the insertion direction of the busbar 2 into the busbar holding portion 32 and the insertion direction of the terminal 9 into the terminal accommodation room 39.

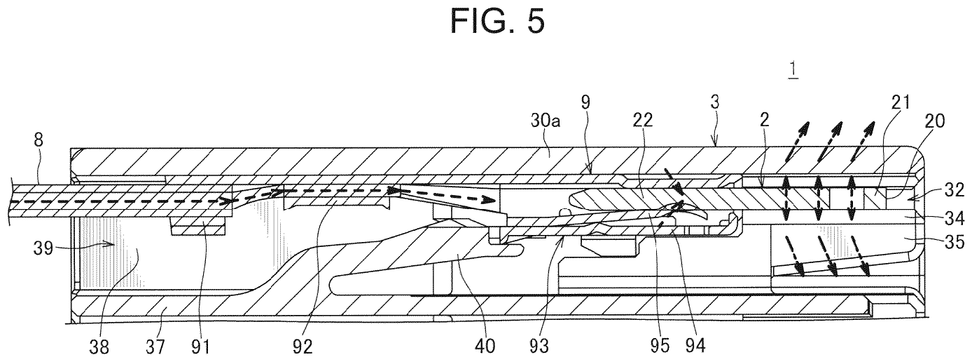

According to the connector 1 having the above-described configuration, as shown by the broken line arrowhead in FIG. 5, the current flows in the order from the electric wire 8 to the terminal 9 and to the busbar 2. The Joule heat is generated by each energized portion in this manner. The generated heat is diffused from the busbar 2 to the surrounding housing 3, and then diffused into the air from the surface of the housing 3, as shown by the dashed-dotted line arrowhead in FIG. 5. According to such a connector 1, the surface area of the housing 3 around the busbar 2 is increased by providing the above-mentioned heat dissipation plate 35, and heat dissipation performance from the surface of the housing 3 into the air is improved. Moreover, since the heat dissipation plate 35 is standing vertically from the clamping plate 34 and is continued to the rear end of the vertical partition wall 38, the rigidity of the busbar holding portion 32 is also improved.

It is noted that the above-described embodiment merely shows a typical aspect of the present invention, and the present invention is not limited to this embodiment. That is, various modifications can be made without departing from the spirit of the present invention. Such modifications are, of course, included within the scope of the present invention as long as they still have the structure according to the present invention.

### REFERENCE SIGNS LIST

1 connector
2 busbar
3 housing
9 terminal
32 busbar holding portion
35 heat dissipation plate
39 terminal accommodation room

What is claimed is:

1. A connector, comprising:
a busbar; and
a housing that accommodates the busbar,
wherein the housing includes a busbar holding portion at one side thereof, and the busbar holding portion includes a pair of clamping plates that clamp the busbar from both sides in a thickness direction thereof,
the housing includes a terminal accommodation room at the other side thereof to accommodate a terminal configured to be electrically connected to the busbar, and
the housing includes a heat dissipation plate standing from one of the pair of clamping plates.

2. The connector according to claim 1,
wherein a plurality of the busbars are provided,
the housing includes a plurality of the busbar holding portions, and the plurality of busbar holding portions are arranged in the thickness direction of the busbars, and
the heat dissipation plate standing from the clamping plate of one of the plurality of busbar holding portions is spaced apart from the clamping plate of another busbar holding portion.

3. The connector according to claim 1, wherein the heat dissipation plate is vertically standing from one of the pair of the clamping plates.

4. The connector according to claim 1, wherein a longitudinal direction of the heat dissipation plate is coincided with an insertion direction of the busbar into the busbar holding portion and an insertion direction of the terminal into the terminal accommodation room.
